(19) United States
(12) Patent Application Publication
(10) Pub. No.: US 2010/0224397 A1
(43) Pub. Date: Sep. 9, 2010

(54) WIRING BOARD AND METHOD FOR MANUFACTURING THE SAME

(75) Inventors: Keisuke Shimizu, Ogaki-shi (JP); Yoichiro Kawamura, Ogaki-shi (JP); Yoji Kitamura, Ogaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: IBIDEN CO., LTD., Ogaki-shi (JP)

(21) Appl. No.: 12/498,813

(22) Filed: Jul. 7, 2009

Related U.S. Application Data
(60) Provisional application No. 61/158,123, filed on Mar. 6, 2009.

(51) Int. Cl. H05K 1/18; H05K 3/30

(52) U.S. Cl. 174/260; 29/832

(57) ABSTRACT

A wiring board has a substrate with an opening section, an electronic component having an electrode and arranged in the opening section, insulative material filled in the gaps between the substrate and the electronic component in the opening section, and a first conductive layer formed on the insulative material and including a first conductive pattern. A via hole is formed in the insulative material. The electrode of the electronic component and the first conductive pattern are connected by means of the via hole. The height of the via hole is set in the range of 5-15 μm and the aspect ratio of the via hole is set in the range of 0.07-0.33.

### CROSS-REFERENCE TO RELATED APPLICATIONS

The present application claims the benefits of priority to U.S. Application No. 61/158,123, filed Mar. 6, 2009. The contents of that application are incorporated herein by reference in their entirety.

### BACKGROUND OF THE INVENTION

1. Field of the Invention

The present invention is related to a wiring board with a built-in electronic component such as a resistor or capacitor, and its manufacturing method.

2. Discussion of the Background

In Japanese Laid-Open Patent Publication 2006-32887, a wiring board with a built-in electronic component and its manufacturing method are described. According to the manufacturing method, a worker manufactures a wiring board with a built-in electronic component by embedding an electronic component in a substrate and electrically connecting a conductive pattern of the substrate and a terminal electrode (electrode pad) of the electronic component through a via hole.

The contents of this publication are incorporated herein by reference in their entirety.

### SUMMARY OF THE INVENTION

A wiring board according to one aspect of the present invention has a substrate having an opening section, an electronic component having an electrode and arranged in the opening section, an insulative material to be filled in the gap between the substrate and the electronic component in the opening section, and a first conductive layer formed on the insulative material and including a first conductive pattern. In such a wiring board, a via hole is formed in the insulative material, the electrode of the electronic component and the first conductive pattern are connected by means of the via hole, the height of the via hole is set in the range of 5-15 μm, and the aspect ratio of the via hole is set in the range of 0.07-0.33.

“Arranged in the opening section” includes cases in which the entire electronic component is completely accommodated in the opening section, along with other cases in which only part of the electronic component is arranged in the opening section.

A method for manufacturing a wiring board according to another aspect of the present invention includes the following steps: preparing a substrate having an opening section; arranging an electronic component having an electrode in the opening section; filling an insulative material in the gap between the substrate and the electronic component in the opening section; forming a first conductive layer including a first conductive pattern on the insulative material; forming a via hole with a height in the range of 5-15 μm and an aspect ratio in the range of 0.07-0.33; and connecting the electrode of the electronic component and the first conductive pattern by means of a via hole.

“prepareing” includes cases in which a worker purchases materials, components and so forth to manufacture a substrate himself, along with cases in which the worker purchases a finished substrate and uses it in the process.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a wiring board according to the First Embodiment of the present invention;

FIG. 2 is a cross-sectional view of an electronic component to be built into the wiring board;

FIG. 3 is a view showing a positional relationship of terminal electrodes of the electronic component and via holes;

FIG. 4A is a magnified view of the electronic component to be built into the wiring board;

FIG. 4B is a magnified view showing part of FIG. 4A;

FIGS. 5A-5B are views illustrating state of how cracks occur in an electronic component;

FIG. 6 is a view showing a sample to be used in simulations;

FIG. 7 is a view showing an electronic component to be built into the sample;

FIG. 8 is a table showing the properties of the materials used in the sample;

FIG. 9 is a table showing the simulation results;

FIG. 10 is a graph showing the data in the table in FIG. 9;

FIG. 11 is a table showing the simulation results listed in order of aspect ratios from smallest to largest;

FIG. 12 is a first graph showing the data in the table in FIG. 11;

FIG. 13 is a second graph showing the data in the table in FIG. 11;

FIG. 14A is a view illustrating the structure of a wiring board according to the First Embodiment of the present invention;

FIG. 14B is a view showing a wiring board (a comparative example) which contains an interlayer insulation layer other than an adhesive agent;

FIG. 15 is a flowchart showing the processes of the method for manufacturing a wiring board according to the First Embodiment of the present invention;

FIGS. 16A-16D are views illustrating steps to arrange an electronic component on a carrier;

FIGS. 17A-17C are views illustrating steps to build (embed) an electronic component into a substrate;

FIGS. 18A-18C are views illustrating steps to form a conductive pattern;

FIG. 19A is a cross-sectional view of a wiring board according to the Second Embodiment of the present invention;

FIG. 19B is a magnified view of an electronic component to be built into the wiring board;

FIG. 20A is a view illustrating a step to prepare a substrate;

FIG. 20B is a view illustrating a step to form a space for building an electronic component into the substrate;

FIG. 20C is a view illustrating a step to mount the substrate on a carrier;

FIG. 20D is a view illustrating a step to arrange an electronic component on the carrier

FIG. 21A is a view illustrating a first step to build (embed) an electronic component into the substrate;

FIG. 21B is a view illustrating a second step to build an electronic component into the substrate;

FIG. 22 is a view illustrating a step to form a conductive pattern;

FIG. 23A is a view showing a first example of a wiring board using a filled via; and

FIG. 23B is a view showing a second example of a wiring board using a filled via.

### DETAILED DESCRIPTION OF THE EMBODIMENTS

The embodiments will now be described with reference to the accompanying drawings, wherein like reference numerals designate corresponding or identical elements throughout the various drawings.

In the following, embodiments of the present invention are described in detail while referring to the drawings.

### First Embodiment

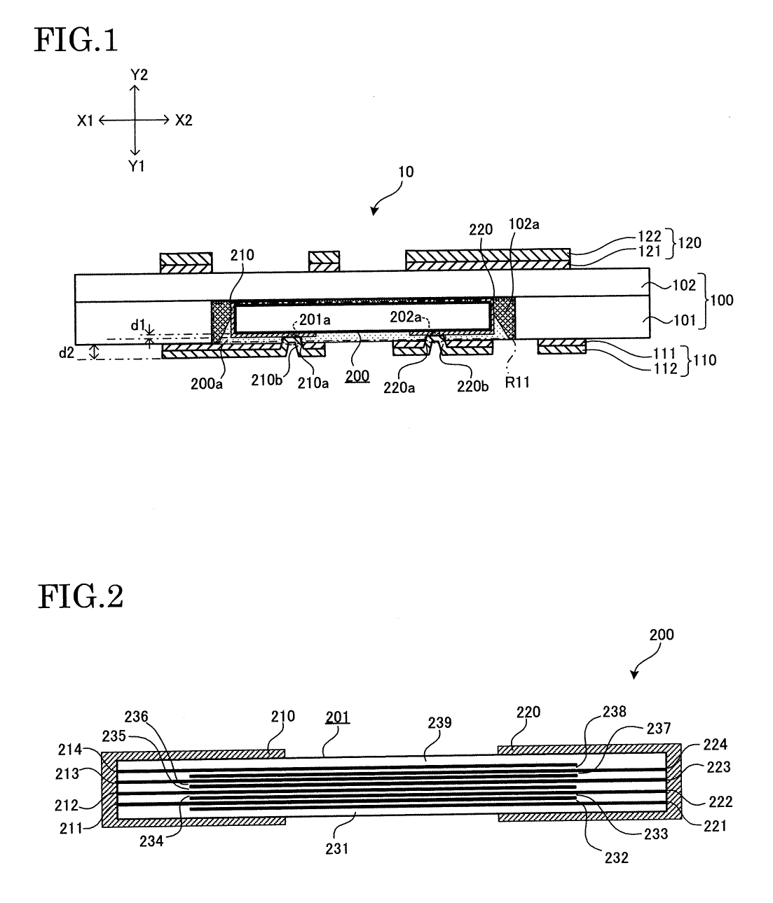

As shown in FIG. 1, wiring board 10 with a built-in electronic component according to the present embodiment has substrate 100, wiring layers (110, 120) as conductive patterns, and electronic component 200.

Substrate 100 is formed with square insulation layers (101, 102) made of cured prepreg, for example. The prepreg is preferred to contain reinforcing material such as glass fiber or aramid fiber, which is then impregnated with resin. Warping or the like is suppressed in substrate 100 because of such reinforcing material. The reinforcing material has a smaller coefficient of thermal expansion than the main material (prepreg).

Insulation layer 101 has opening section (R11) configured to correspond to the external shape of electronic component 200. Opening section (R11) will become a hollow section of substrate 100 in the present embodiment.

The configuration, material, etc., of substrate 100 may be modified according to usage requirements or the like. For example, the following may also be used as prepreg: base material such as glass fiber or aramid fiber impregnated with resin such as epoxy resin, bismaleimide triazine resin (BT resin), imide resin (polyimide), allyl polyphenylene ether resin (A-PPE resin) or the like. Also, instead of prepreg, liquid or film-type thermosetting resins or thermoplastic resins may be used. As for thermosetting resins, for example, epoxy resin, imide resin (polyimide), BT resin, allyl polyphenylene ether resin, aramid resin or the like may be used. As for thermoplastic resins, for example, liquid crystal polymer (LCP), PEEK resin, PTFE resin (fluororesin) or the like may be used. Such resins are preferred to be selected according to requirements such as insulation, dielectric properties, heat resistance and mechanical features. In addition, such resins may contain curing agents, stabilizers, fillers or the like as additives. Alternatively, instead of prepreg, resin-coated copper foil (RCF) or the like may also be used.

On the surfaces (both surfaces) of substrate 100, wiring layers (110, 120) are formed: Wiring layer 110 is formed on the lower surface of substrate 100 (the surface on the arrow-Y1 side); and wiring layer (120) is formed on the upper surface of substrate 100 (the surface on the arrow-Y2 side).

Wiring layer 110 is formed with first wiring layer 111 and second wiring layer 112; and wiring layer 120 is formed with first wiring layer 121 and second wiring layer 122. First wiring layers (111, 121) are made of for example, copper foil. Second wiring layers (112, 122) are made of, for example, copper-plated film. Since wiring layers (110, 120) include first wiring layers (111, 121) (metal foil) and second wiring layers (112, 122) (plated-metal film), adhesiveness improves between first wiring layers (111, 121) and insulation layers (101, 102), and they will seldom suffer delamination. The thickness of wiring layers (110, 120) is set, for example, in the range of 15-40 μm. Here, the material, thickness and so forth of wiring layers (110, 120) may be modified according to usage requirements or the like.

In opening section (R11), electronic component 200 is arranged, which has substantially the same thickness as insulation layer 101. Along with adhesive (200a) to secure electronic component 200, insulative resin (102a) that has seeped (drained) from insulation layers (101, 102) fills in the boundary portions between electronic component 200 and substrate 100. Resin (102a) completely envelops electronic component 200. In doing so, electronic component 200 is protected by resin (102a) and is fixed to a predetermined position.

Adhesive (200a) is made from insulative material such as non-conductive liquid polymer (NCP). Taper-shaped via holes (201a, 202a) are formed in insulative adhesive (200a). More specifically, in first wiring layer 111 and adhesive (200a), tapered penetrating holes (210a, 220a) are formed to be connected to electronic component 200. Via holes (201a, 202a) are formed as part of penetrating holes (210a, 220a) respectively. In addition, on the wall and bottom surfaces of penetrating holes (210a, 220a), conductors (210b, 220b) that are contiguous to second wiring layer 112 are formed. Therefore, on the wall and bottom surfaces of via holes (201a, 202a) which are part of penetrating holes (210a, 220a), conductors (210b, 220b) are also formed respectively. Via hole (201a) and conductor (210b), and via hole (202a) and conductor (220b) each form a conformal via. Electronic component 200 and wiring layer 110 are electrically connected by means of such conformal vias.

In the present embodiment, the elastic modulus of adhesive (200a) is lower than the elastic modulus of resin (102a). By forming via holes (201a, 202a) in adhesive (200a) having a relatively lower elastic modulus, stress exerted on conductors (210b, 220b) inside via holes (201a, 202a) will be mitigated. Also, in the rest of the area, electronic component 200 is enveloped by resin (102a) having a relatively higher elastic modulus. Thus, the strength of electronic component 200 increases against impact from outside. The elastic modulus of adhesive (200a) is preferred to be in the range of 1-9 GPa. In the present embodiment, adhesive (200a) with elastic modulus 4 GPa is used. The elastic modulus of resin (102a) is preferred to be in the range of 5-22 GPa. In the present embodiment, resin (102a) with elastic modulus 7 GPa is used.

Electronic component 200 is a chip capacitor, for example. More specifically, as its cross-sectional structure shows in FIG. 2, electronic component 200 is formed with capacitor body 201 and U-shaped terminal electrodes (210, 220) (electrode pads). Capacitor body 201 is formed, for example, by alternately laminating multiple dielectric layers (231-239), made of ceramic, for example, and multiple conductive layers (211-214) and (221-224). Terminal electrodes (210, 220) are formed on both ends of capacitor body 201 respectively. Both ends of capacitor body 201, specifically, their lower surfaces, side surfaces and upper surfaces, are covered by terminal electrodes (210, 220) respectively. Since side surfaces of capacitor body 201 are covered by terminal electrodes (210, 220), efficiency in generating heat increases. Meanwhile, the central section of capacitor body 201 is exposed. Electronic component 200 is not limited to a chip capacitor, and other passive components such as a chip resistor may also be used as electronic component 200.

As shown in FIG. 1, while being built into substrate 100, the lower surfaces of terminal electrodes (210, 220) of electronic component 200 are connected to wiring layer 110 by means of via hole (201a) and conductor (210b) and by via hole (202a) and conductor (220b) respectively. Here, second wiring layer 112 and conductors (210b, 220b) are made of copper-plated film, for example. Thus, reliability in the connected portions is high between electronic component 200 and wiring layer 110. Also, by forming plated-metal film on the surface of terminal electrode 210 of electronic component 200, reliability in the connected portions further increases between electronic component 200 and wiring layer 110.

Meanwhile, the central section of capacitor body 201 (FIG. 2) is coated with resin (102a). Since areas where relatively fragile ceramic portions are exposed (the central section) in capacitor body 201 are coated with resin (102a), capacitor body 201 is protected by such resin (102a).

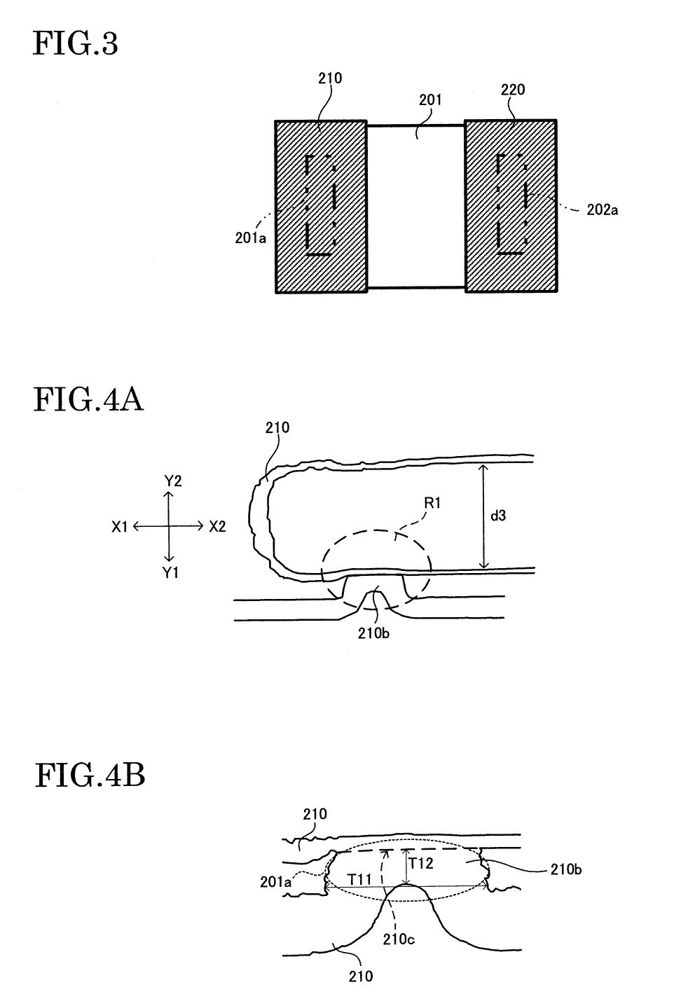

Via holes (201a, 202a) are positioned respectively in the center of terminal electrodes (210, 220) of electronic component 200, as shown in FIG. 3.

FIG. 4A is a magnified view showing part of electronic component 200. FIG. 4B is a magnified view of region (R1) in FIG. 4A. The external shape of electronic component 200 is, for example, configured to be 1 mm by 1 mm square, and thickness (d3) of electronic component 200 is set in the range of 100-150 μm, for example. Via holes (201a, 202a) are connected to the lower surface (the surface on the arrow-Y1 side) of electronic component 200.

The surfaces of terminal electrodes (210, 220) are roughened. Since connection surface (210c) between terminal electrode 210 and conductor (210b) is roughened, adhesiveness improves between terminal electrode 210 and conductor (210b).

For the sake of convenience, only the side of terminal electrode 210 is shown in FIGS. 4A and 4B. However, the same applies to the side of terminal electrode 220.

The thickness of terminal electrodes (210, 220), especially thickness (d1) (FIG. 1) on their lower-surface side to which conductors (210b, 220b) are connected, is preferred to be set in the range of 2-15 μm, more preferably at 5 μm.

If terminal electrode 210 or 220 becomes thinner, its strength decreases accordingly. Therefore, if terminal electrode 210 or 220 is too thin, when forming via hole (201a) or (202a) by laser or the like, such a drilling process may not stop at terminal electrode 210 or 220, but may bore into terminal electrode 210 or 220.

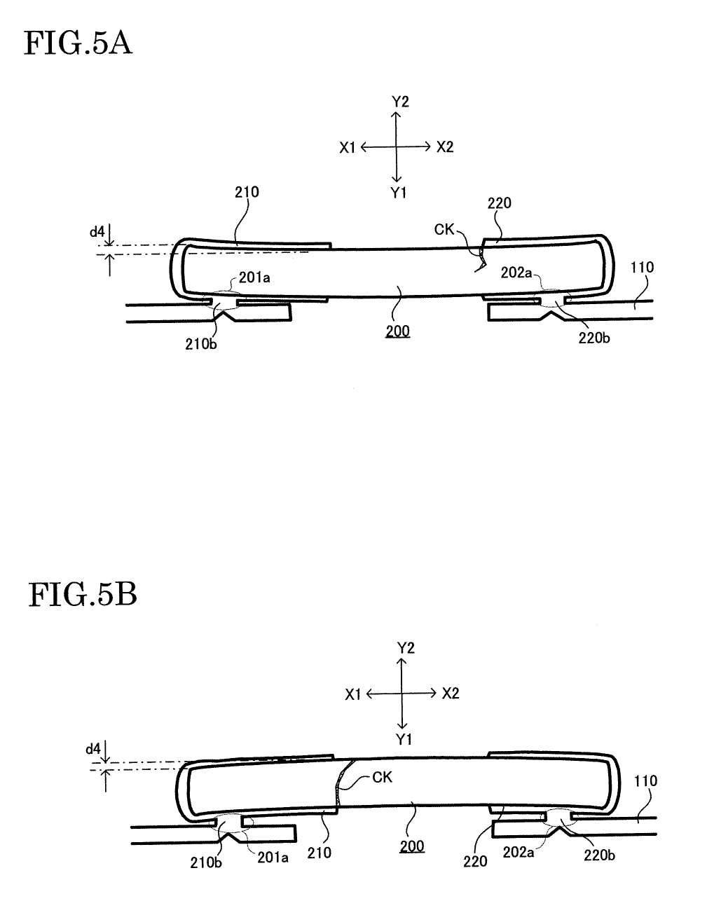

On the other hand, if terminal electrode 210 or 220 is too thick, as shown in FIGS. (5A) or (5B), there may be a concern that cracks (CK) will occur in the boundary areas of electronic component 200 between where electrodes are formed and where electrodes are not formed. When electronic component 200 becomes even more compact, electronic component 200 tends to warp by protruding downward (FIG. 5A) or upward (FIG. 5B). The degree of warping (d4) of electronic component 200 is in the range of 5-15 μm, for example.

In addition, if terminal electrode 210 or 220 becomes thicker, wiring board 10 with a built-in electronic component becomes larger accordingly, causing drawbacks in terms of mounting space or the like.

However, if the thickness of terminal electrodes (210, 220) is in the above range, wiring board 10 with a built-in electronic component may be formed with fewer such drawbacks in terms of strength and cracking or the like.

Thickness (d2) (FIG. 1) of wiring layer 110 is preferred to be set in the range of 15-40 μm, more preferably at 30 μm.

If wiring layer 110 becomes too thin, electronic resistance increases. This is not preferred in terms of energy efficiency or the like.

On the other hand, if wiring layer 110 is too thick, it takes longer to form such layers, which is not preferable for manufacturing efficiency. Especially, when wiring layer 110 is formed by plating, drawbacks such as difficulty in depositing uniform plated-metal film or difficulty in forming and removing plating resist may arise.

However, if the thickness of wiring layer 110 is in the above range, wiring board 10 with a built-in electronic component may be manufactured with fewer such drawbacks in terms of energy efficiency and manufacturing efficiency.

In addition, the ratio between the thickness (d1) of terminal electrode 210 or 220 and thickness (d2) of wiring layer 110 is preferred to be set so that the thickness of terminal electrode 210 or 220 is less than the thickness of wiring layer 110. Especially, the thickness of terminal electrode 210 or 220 is preferred to be set at half (½) or smaller than half the thickness of wiring layer 110. With such a ratio, terminal electrode 210 or 220 becomes thinner, and cracking or the like may be suppressed from occurring in electronic component 200. Meanwhile, the thickness of wiring layer 110 is made relatively thicker to compensate for the reduced thickness of terminal electrode 210 or 220, and thus a high level of heat dissipation may be maintained.

The diameter (T11) (FIG. 4B) of via holes (201a, 202a) is preferred to be set in the range of 30-70 μm, more preferably 50-60 μm. If the diameter of via hole (201a) or (202a) is too small, connection reliability will decrease. On the other hand, if the diameter of via hole (201a) or (202a) is too large, the areas required for terminal electrodes (electrode pads) (210, 220) of electronic component 200 will increase, thus making it hard to highly integrate electronic components 200. However, if the diameter of via holes (201a, 202a) is set in the above range, wiring board 10 with a built-in electronic component may be manufactured with fewer such drawbacks. If all the diameters of tapered via holes (201a, 202a) or the like are not the same in the direction of their heights, the average value is used as diameter (T11).

Height (T12) (FIG. 4B) of via holes (201a, 202a) is preferred to be set in the range of 5-15 μm, more preferably at 10 μm. If the height of via holes (201a, 202a) is too low, it is difficult to form uniform holes. On the other hand, if the height of via holes (201a, 202a) is too tall, it takes longer to form such holes, leading to drawbacks in light of manufacturing efficiency. However, if the height of via holes (201a, 202a) is set in the above range, wiring board 10 with a built-in electronic component may be manufactured with fewer such drawbacks.

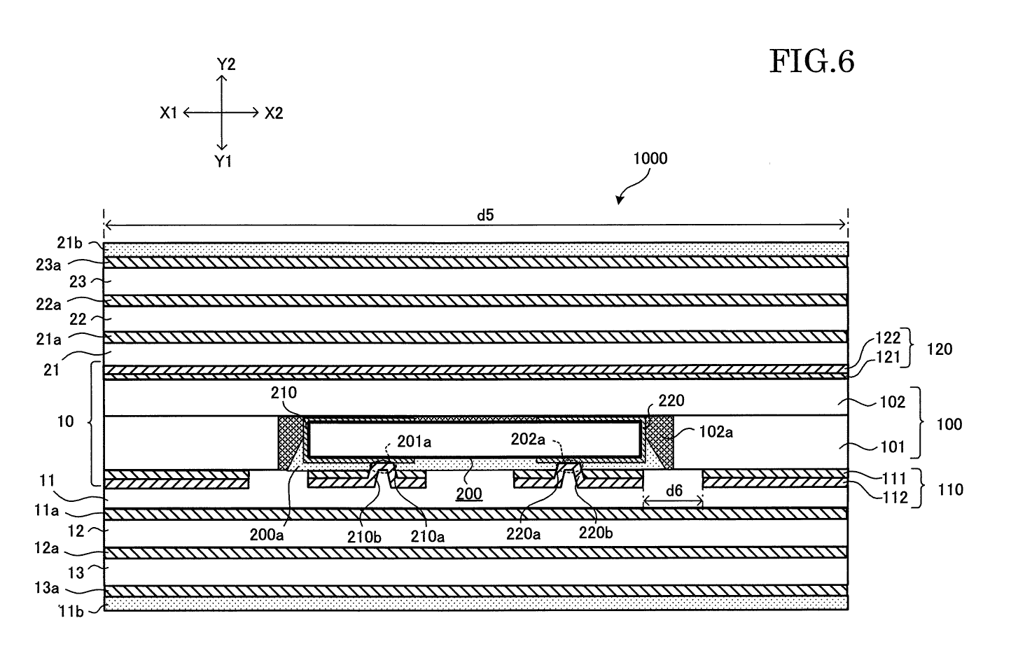

The aspect ratio (height T12/diameter T11) of via holes (201a, 202a) is preferred to be set in the range of 0.07-0.33, more preferably 0.07-0.20. Regarding such ratios, the simulation results of wiring board 10 with a built-in electronic component are described with reference to FIGS. 6-13.

The simulations were conducted on sample 1000 having a structure shown in FIG. 6. Width (d5) of sample 1000 is 3,600 μm. Sample 1000 has a symmetrical structure, with the arrow-X1 side being symmetrical to the arrow-X2 side and with the axis of symmetry being the center line of width (d5). Basically, sample 1000 is formed by laminating insulation layers (11-13, 21-23), conductive layers (11a-13a, 21a-23a) and solder-resist layers (11b, 21b) onto both surfaces (upper and lower surfaces) of wiring board 10 with a built-in electronic component. However, wiring layers (110, 120) are not patterned in sample 1000. Wiring layer 110 is divided into the area to be connected to electronic component 200 and the area to be separated from electronic component 200. Such areas are separated by distance (d6) (=200 μm) at their boundaries.

The thickness of each layer is set as follows: 200 μm at substrate 100 (core); 60 μm at insulation layers (11-13, 21-23); 30 μm at wiring layers (110, 120); 25 μm at conductive layers (11a, 12a, 21a, 22a); 30 μm at conductive layers (13a, 23a); and 20 μm at solder-resist layers (11b, 21b).

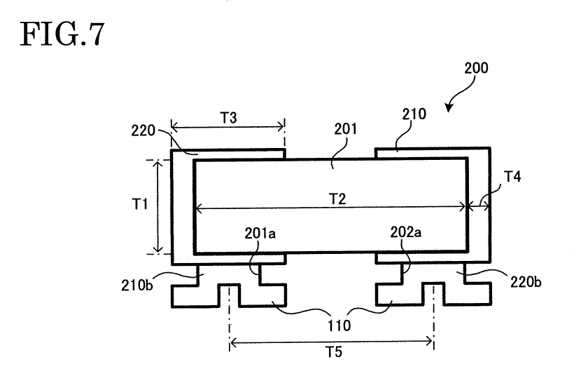

The dimensions of each portion of electronic component 200 are described with reference to FIG. 7. Thickness (T1) of capacitor body 201 is set at 150 μm, width (T2) of capacitor body 201 at 1,000 μm, length (T3) of terminal electrodes (210, 220) in directions X (directions of arrows X-1 and X-2) on upper and lower surfaces of electronic component 200 at 300 μm, thickness (T4) of terminal electrodes (210, 220) on side surfaces of electronic component 200 at 10 μm, and distance (T5) between terminal electrode 210 and terminal electrode 220 at 720 μm.

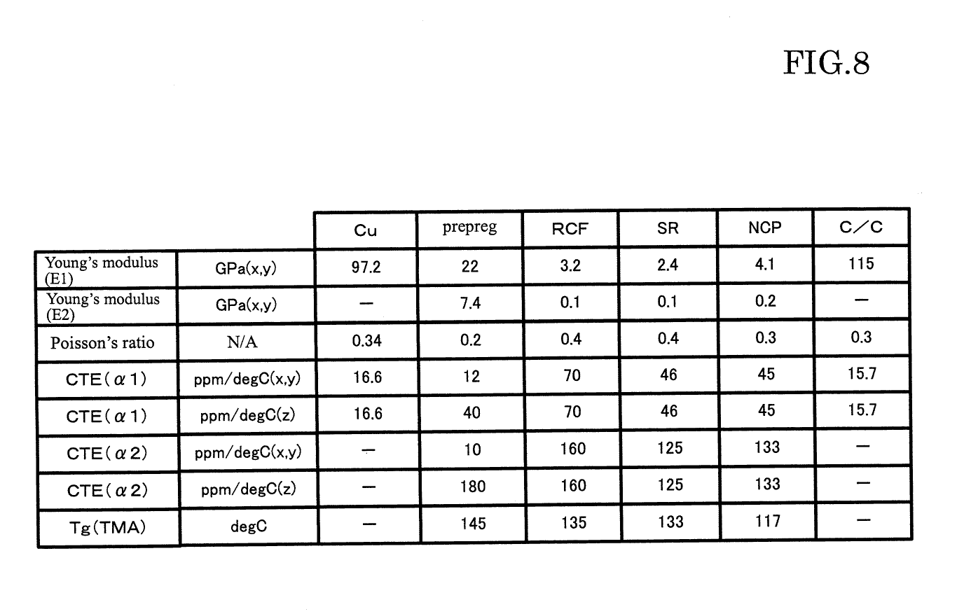

The material for each layer is as follows: prepreg (R1551) for substrate 100 (core) and insulation layers (11, 12, 21, 22); RCF (MRG 200) for insulation layers (13, 23); copper for wiring layers (110, 120) and conductive layers (11a-13a, 21a-23a); PSR 4000 for solder-resist layers (11b, 21b); and BaTiO3 for the chip capacitor (C/C). In addition, the material for adhesive (200a) is NCP. For information, FIG. 8 shows Young's modulus, Poisson's ratio, coefficients of thermal expansion (CTE), and glass transition temperature (Tg) (TMA) of each material.

The person who took measurements conducted simulations on sample 1000 by changing diameter (T11) and height (T12) of via holes (201a, 202a). More specifically, a two-dimensional model was used to measure equivalent stresses in an environment without external stresses (stress free) while changing the temperature from 125° C. to −55° C. The ranges used in the simulations were as follows: 10-110 μm for diameter (T11) of via holes (201a, 202a); and 5-15 μm for height (T12) of via holes (201a, 202a).

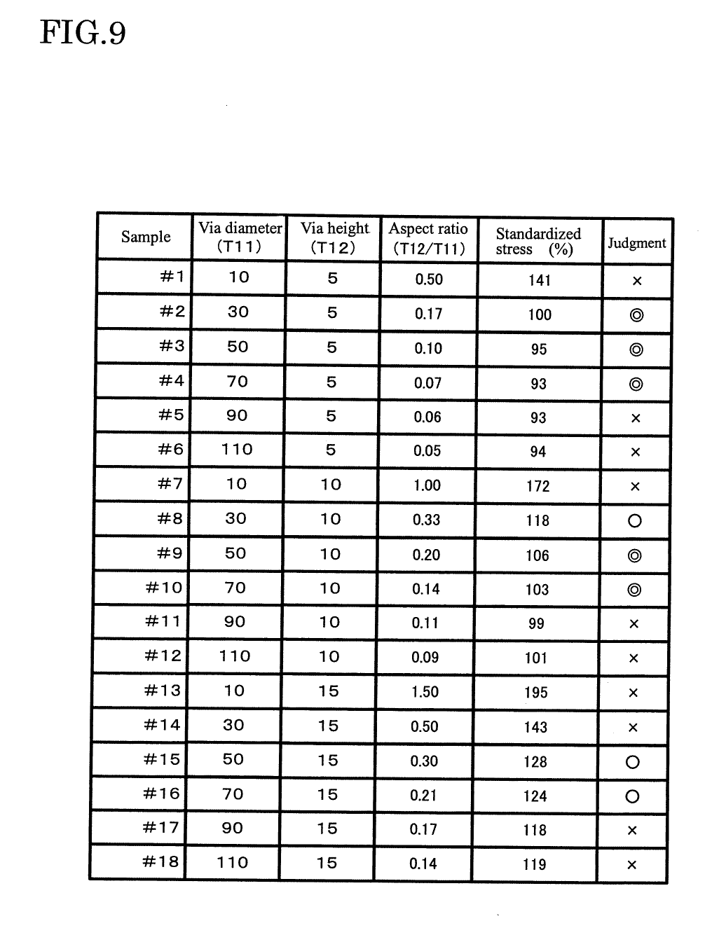

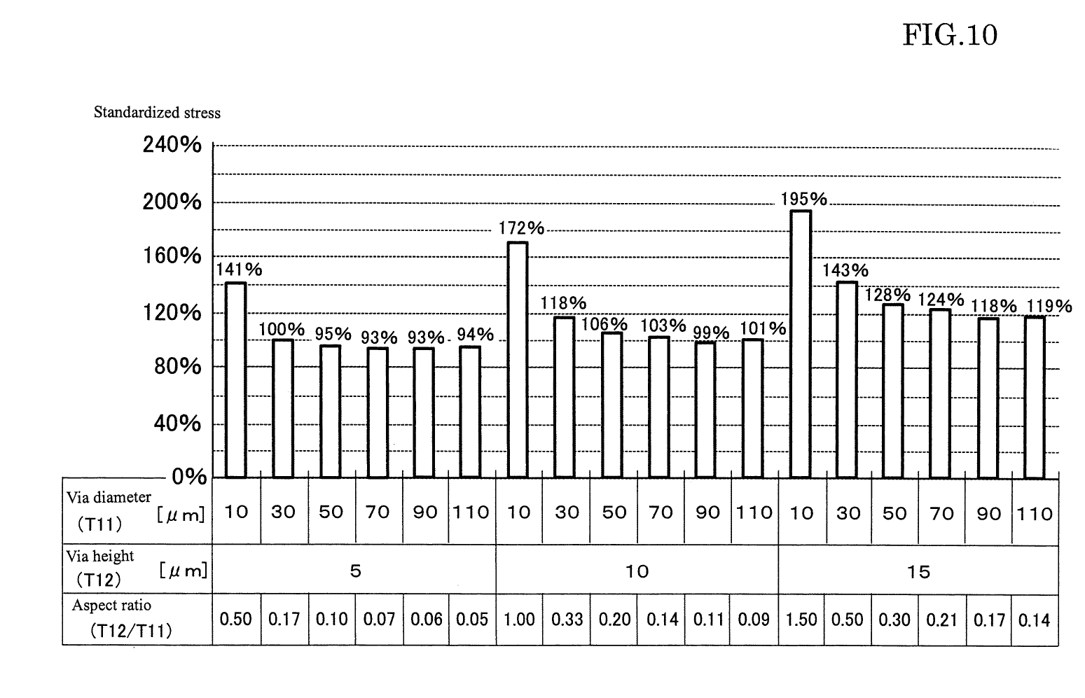

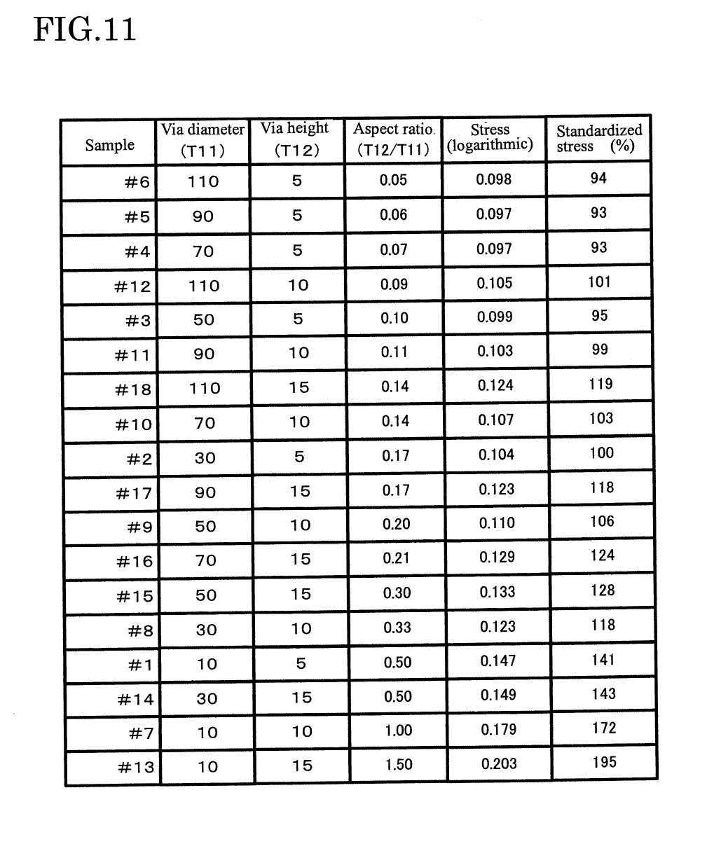

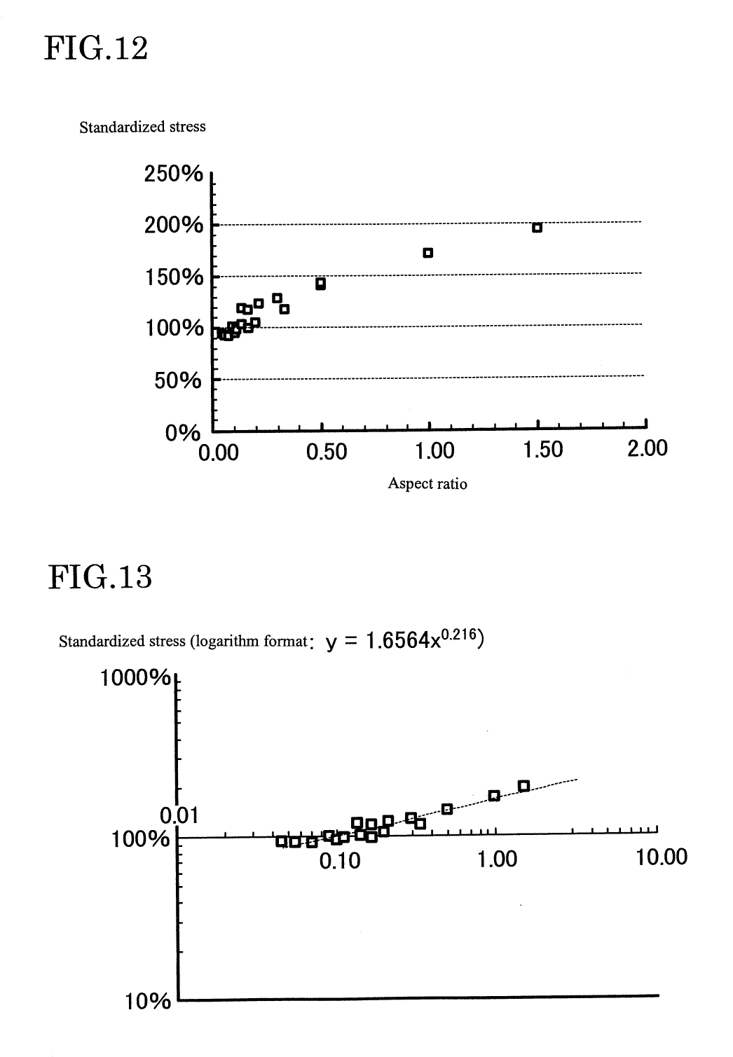

FIGS. 9-13 show the simulation results. As simulations were conducted on samples #1-#18, results shown in FIG. 9 were obtained. FIG. 10 is a graph showing the data in FIG. 9. FIG. 11 lists the simulation results in order of aspect ratios from smallest to largest showing the data in FIG. 9 and those data transformed into logarithm format. FIGS. 12 and 13 are graphs showing data in FIG. 11. In those tables and graphs, “standardized stress” indicates the percentage of the stress in each wiring board when the stress in a wiring board (the base wiring board) is set as base (100%). Diameter (T1) of the base wiring board is set at 30 μm and height (T12) at 5 μm; if set as such, excellent results are most likely expected.

As shown in FIGS. 9 and 10, generally speaking, by increasing diameter (T11) of via holes (201a, 202a), equivalent stresses decrease accordingly and then converge to a certain value. Also, by reducing height (T12) of via holes (201a, 202a), equivalent stresses decrease. Therefore, by increasing diameter (T11) and reducing height (T12), a decrease in equivalent stresses may be expected. Regarding such tendencies, the inventors assume the following: Namely, if diameter (T11) increases, the hole size increases accordingly, and force concentrated around the central portions of via holes (201a, 202a) tends to be dispersed to the edge portions; thus, stresses decrease as diameter (T11) increases. Also, the inventors assume the following: If height (T12) increases, force at the edges (angles) of via holes (201a, 202a) will concentrate in the central portions to cause an increase in the moment of force; thus, stresses increase as height (T12) increases.

As shown in FIGS. 11 and 12, generally speaking, by increasing aspect ratios, equivalent stresses increase and then converge to a certain value. Also, as shown in FIGS. 11 and 13, the relationship between aspect ratios and equivalent stresses in logarithm format is shown in substantially a straight line. Accordingly, aspect ratios and equivalent stresses are thought to be correlated.

If stress increases in samples #1-#18, there is a concern that cracks or the like will occur. Also, if height (T12) becomes too great, stress will concentrate more in the central portions of via holes (201a, 202a) than in their edges, thus reducing connection reliability. Regarding such concerns, quality was judged for each one of samples #1-#18 and the results are shown in FIG. 9 (⊚: very good, ◯: good, ×: not good). Samples #5, #6, #11, #12, #17 and #18, each having diameter (T11) of 90 μm or 110 μm, have small stress values in the simulations. However, since areas required for terminal electrodes (210, 220) increase in electronic component 200, those samples are not suitable when electronic components 200 are mounted with high density. Thus, the quality for those samples is judged as “×”.

According to such results, when diameter (T11) is set at 5 μm, the aspect ratio is preferred to be in the range of 0.07-0.17. When diameter (T11) is set at 10 μm, the aspect ratio is preferred to be in the range of 0.14-0.33, more preferably 0.14-0.20. Also, when diameter (T11) is set at 15 μm, the aspect ratio is preferred to be in the range of 0.21-0.30.

Therefore, if diameter (T11) is set in the range of 30-70 μm, the aspect ratio is preferred to be in the range of 0.07-0.33, more preferably 0.07-0.20.

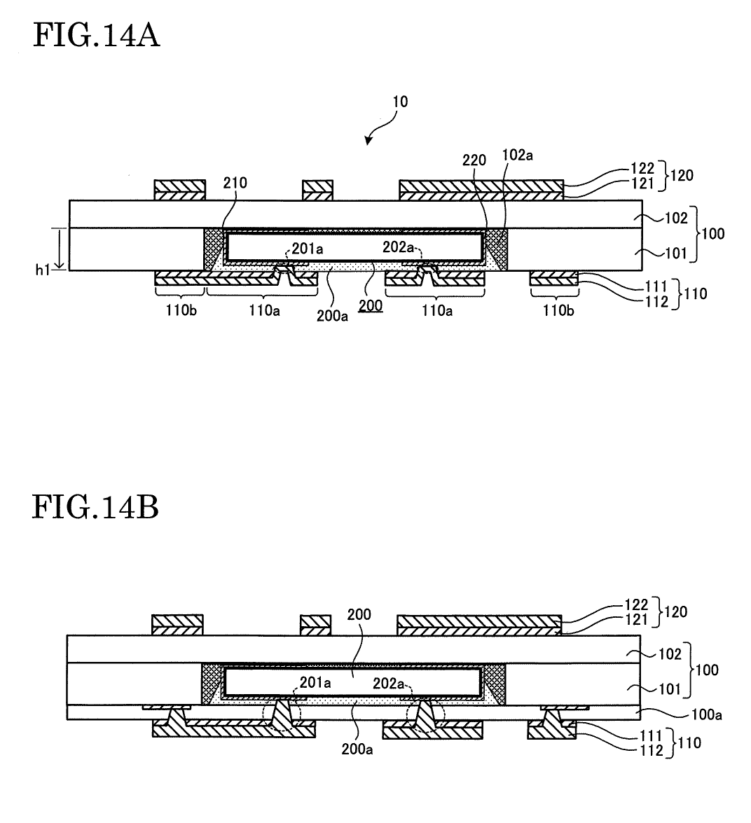

As shown in FIG. 14A, in wiring board 10 with a built-in electronic component, first conductive layer (110a) is formed on adhesive (200a) and second conductive layer (110b) is formed on the lower surface of substrate 100, both of which are part of wiring layer 110. First conductive layer (110a) and second conductive layer (110b) are the conductive layers formed on the same level. Namely, they are formed on the same surface. Here, “the same surface” indicates that the distance from the core (base substrate for lamination) to that surface, namely, height (h1) in the direction of lamination, is the same.

Terminal electrodes (210, 220) of electronic component 200 and first conductive layer (110a) are connected by means of via holes (201a, 202a). Namely, other than adhesive (200a), interlayer insulation layers such as interlayer insulation layer (100a) as shown in FIG. 14B (Comparative Example) are not contained in wiring board 10 with a built-in electronic component. Accordingly, height (T12) of via holes (201a, 202a) may be set at a small value within the above range. As a result, their aspect ratios may be set at a small value within the above range.

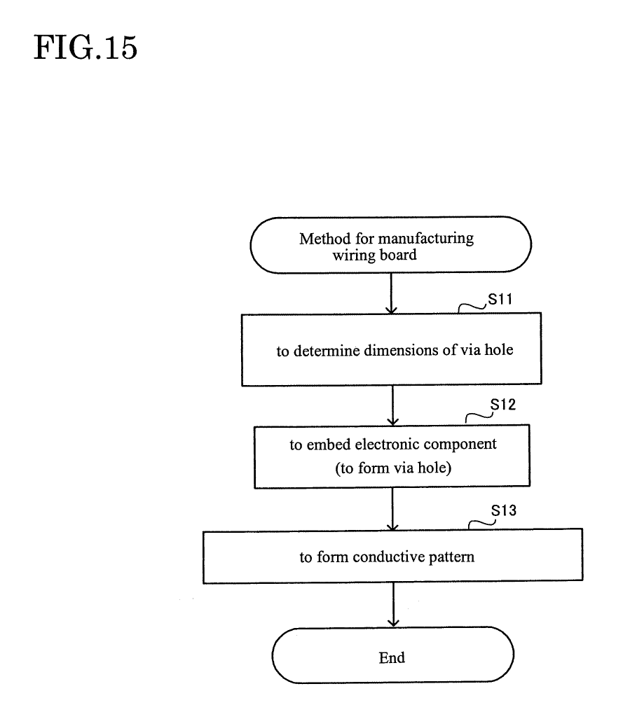

When manufacturing wiring board 10 with a built-in electronic component, for example, a series of processes shown in FIG. 15 are carried out.

In step (S11), diameter (T11), height (T12) and aspect ratio of via holes (201a, 202a) are determined. More specifically, the worker determines the following values: diameter (T11) in the range of 30-70 μm; height (T12) in the range of 5-15 μm; and aspect ratio in the range of 0.07-0.33 (see FIG. 11).

In step (S12), electronic component 200 is embedded through the steps shown in FIGS. (16A-17C).

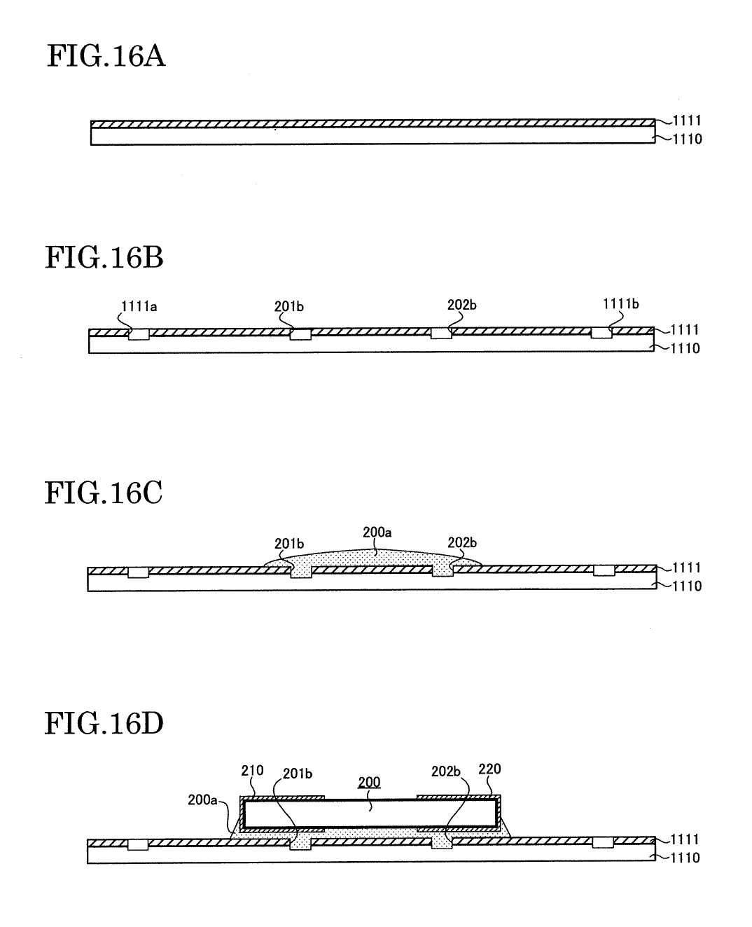

Specifically, carrier 1110 having conductive film 1111 is prepared on one side as shown in FIG. 16A, for example. Carrier 1110 and conductive film 1111 are both made of copper, for example. However, carrier 1110 is thicker than conductive film 1111.

Holes are made using a UV laser or the like to penetrate only conductive film 1111 as shown in FIG. 16B. Accordingly, opening portions (201b, 202b, 1111a, 1111b) are formed. Opening portions (1111a, 1111b) are used as alignment targets.

As shown in FIG. 16C, adhesive (200a) is applied in the central area of carrier 1110 and conductive film 1111 including at least opening portions (201b, 202b) using NCP coating, for example. By doing so, adhesive (200a) is filled in opening portions (201b, 202b).

Electronic component 200 is mounted on opening portions (201b, 202b) as shown in FIG. 16D.

Specifically, electronic component 200 with terminal electrodes (210, 220) is prepared and the surfaces of terminal electrodes (210, 220) are roughened. After electronic component 200 is mounted on adhesive (200a), electronic component 200 is fixed to that position by adding pressure and heat, for example. During that time, electronic component 200 is pressed down so that the thickness of adhesive (200a) will become uniform under electronic component 200 and voids will not remain inside. Such a process is important to secure the connection reliability of via holes (201a, 202a) in the later process. The surfaces of terminal electrodes (210, 220) are usually roughened when those electrodes are formed. However, according to requirements, the surfaces may be roughened using chemicals or the like after the electrodes are formed.

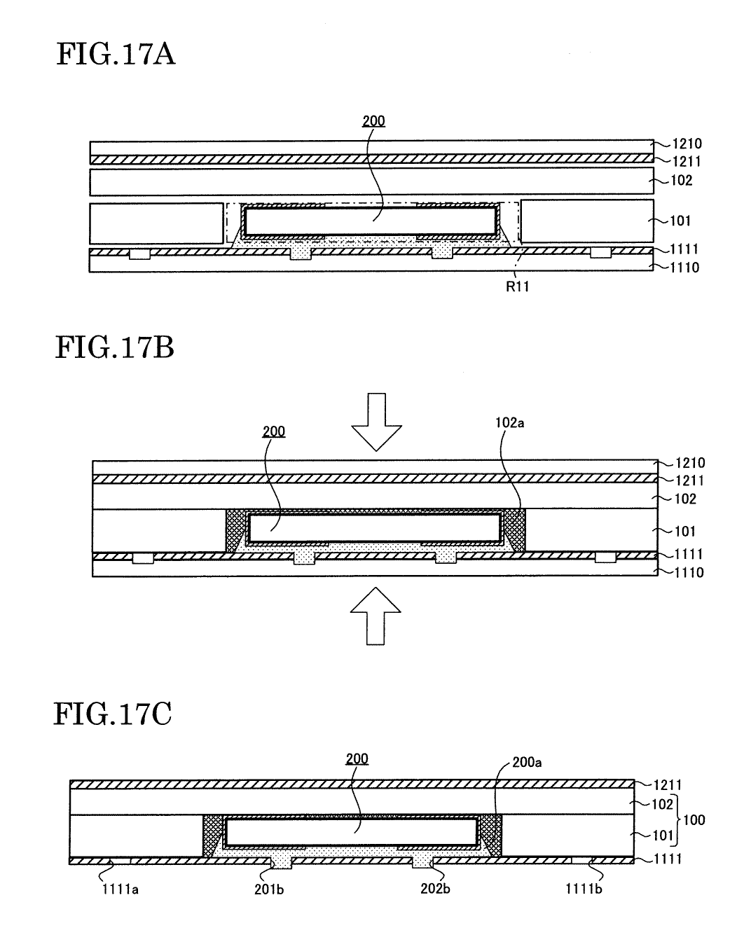

As shown in FIG. 17A, for example, on carrier 1110 and conductive film 1111 made of copper, for example, insulation layer 101 made of prepreg, for example, is formed to be set horizontal to electronic component 200; and further on the top, insulation layer 102 made of prepreg, for example, and conductive film 1211 and carrier 1210 made of copper, for example, are each arranged. Electronic component 200 is arranged in opening section (R11) in the center of insulation layer 101.

Pressure-pressing (for example, thermal pressing) is conducted as shown in FIG. 17B, for example. In doing so, resin (102a) is squeezed out from insulation layers (101, 102). Namely, by such pressing, resin (102a) seeps from (drains from) each prepreg that forms insulation layers (101, 102) and fills the gaps (boundary portions) between electronic component 200 and insulation layer 101. After that, insulation layers (101, 102) are cured through a thermal process, for example.

Carriers (1110, 1210) are removed as shown in FIG. 17C, for example. In doing so, conductive films (1111, 1211) and adhesive (200a) filled in opening portions (201b, 202b) are exposed.

Accordingly, electronic component 200 is embedded in substrate 100. Electronic component 200 is arranged in the hollow section (opening section R11) of substrate 100.

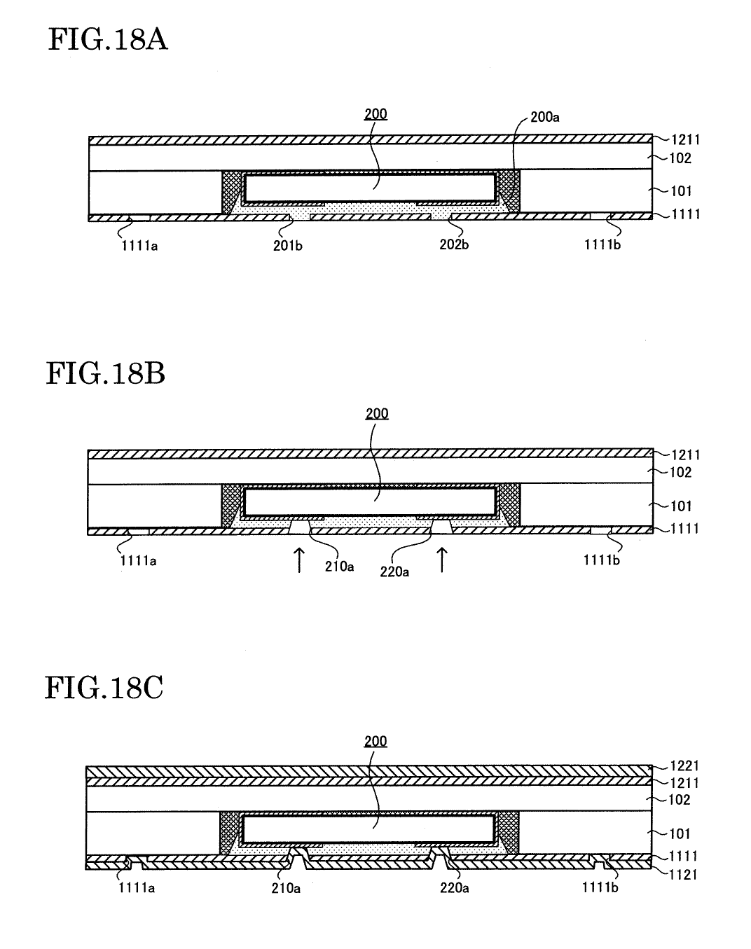

In step (S13) of FIG. 15, conductive patterns are formed through the steps shown in FIGS. 18A-18C.

More specifically, adhesive (200a) is removed from the surface of conductive film 1111 as shown in FIG. 18A. Such a step of removing adhesive (200a) may be omitted if not necessary.

Penetrating holes (210a, 220a) are formed in conductive film 1111 and adhesive (200a) to reach electronic component 200 using a laser or the like as shown, for example, in FIG. 18B. In doing so, via holes (201a, 202a) are formed as part of penetrating holes (210a, 220a). Diameter (T11), height (T12) and aspect ratio of via holes (201a, 202a) are each set as determined in step (S11). Then, CO₂-laser cleaning and desmearing are conducted according to requirements.

As shown in FIG. 18C, for example, PN plating (such as chemical copper plating and copper electroplating) is performed to form conductive films (1121, 1221) (copper-plated films) on the surfaces of conductive films (1111, 1211) including penetrating holes (210a, 220a) and opening portions (1111a, 1111b).

After thinning conductive films (1121, 1221) to the predetermined thickness according to requirements by half etching, for example, a predetermined lithography process (preliminary treatment, lamination, exposure and development, etching, removal of the film, inner-layer inspection and so forth) is conducted to pattern conductive films (1111, 1121, 1211, 1221) in such a configuration as shown in FIG. 1. In doing so, first wiring layer 111 and second wiring layer 112 (wiring layer 110) along with first wiring layer 121 and second wiring layer 122 (wiring layer 120) are formed. Instead of using such a subtractive method to form conductive patterns, another method, a so-called semi-additive (SAP) method, may also be used; namely, plating resist is formed on insulation layers (101, 102), and wiring layers (110, 120) are formed by pattern plating (such as chemical copper plating and copper electroplating). Alternatively, through-holes may also be formed by forming openings that penetrate insulation layers (101, 102) prior to forming conductive patterns, and then performing plating in such openings while forming wiring layers (110, 120). However, the step to adjust the thickness of conductive films (1121, 1221) using half-etching or the like before patterning is not always required. Such a step may be omitted according to usage requirements or the like.

Also, electrodes are formed by chemical gold plating or the like according to requirements, and conducts external processing, warping correction, conductivity inspection, exterior inspection and final inspection. In doing so, wiring board 10 with a built-in electronic component is completed as shown in FIG. 1.

In the present embodiment, the aspect ratio of via holes (201a, 202a) is set in the range of 0.07-0.33.

By forming via holes (201a, 202a) with a low aspect ratio, stresses exerted on via holes (201a, 202a) will be reduced during a heat cycle in the range of −25° C. to 140° C. Therefore, the connection reliability of via holes (201a, 202a) is excellent.

Height (T12) is reduced without making diameter (T11) of via holes (201a, 202a) too large. Accordingly, substrate 100 into which to build electronic component 200 may be formed thinner.

Also, by lowering height (T12), the gap between the upper surface of electronic component 200 (the surface on the arrow-Y2 side in FIG. 1) and substrate 100 may be enlarged. Then, by enlarging the gap, resin (102a) is filled to be sufficiently thick. Thus, resin (102a) may be suppressed from peeling caused by faulty adhesion between the reinforcing material of substrate 100 and electronic component 200.

In addition, by reducing diameter (T11), the areas required for terminal electrodes (210, 220) of electronic component 200 may be decreased. As a result, electronic components 200 may be arranged with high density.

According to the manufacturing method of the present embodiment, wiring board 10 with a built-in electronic component featuring the above structure may be easily manufactured using a simplified method.

### Second Embodiment

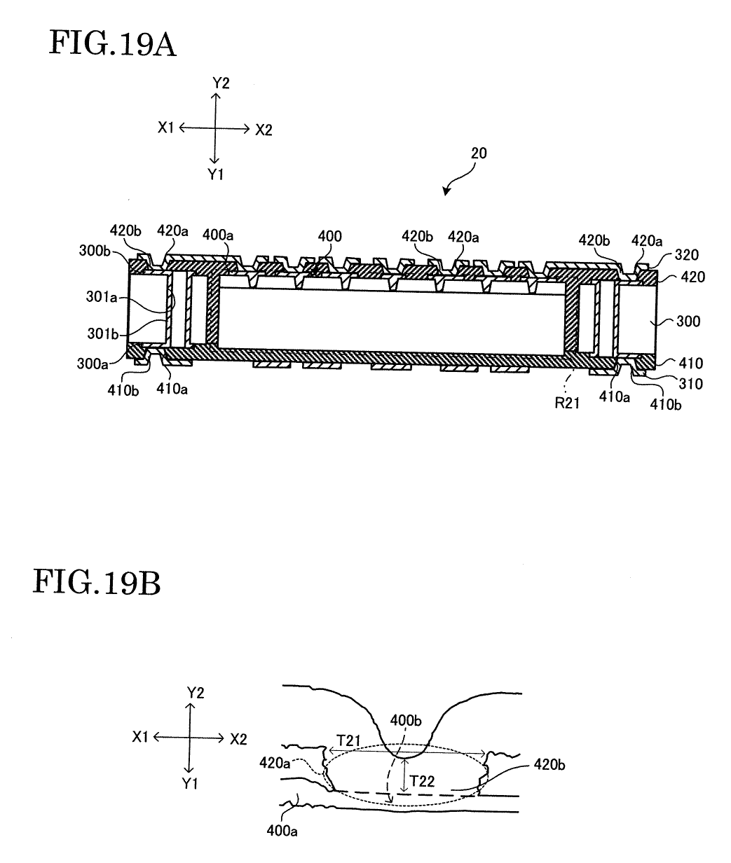

As shown in FIG. 19A, wiring board 20 with a built-in electronic component of the present embodiment has substrate 300, wiring layers (310, 320) as conductive patterns, and electronic component 400. Electronic component 400 is built into wiring board 20 as its built-in electronic component. Electronic component 400 is an IC chip with predetermined integrated circuits. Electronic component 400 has multiple terminal electrodes (400a) (electrode pads) on one surface. The surfaces of terminal electrodes (400a) are roughened. An IC chip referred to here includes a so-called wafer-level CSP, which is formed by forming protective films, terminals, etc., on a wafer, further rewiring and so forth, then by separating the wafers into units. Also, electronic component 400 may have terminal electrodes (400a) on both surfaces.

Substrate 300 is made from, for example, epoxy resin. The epoxy resin is preferred to contain reinforcing material such as glass fiber or aramid fiber impregnated with resin. The reinforcing material has a smaller thermal expansion coefficient than the primary material (epoxy resin). The thickness of substrate 300 is, for example, 0.1 mm. However, the configuration, thickness, material and so forth of substrate 300 may be modified according to usage requirements or the like.

Substrate 300 has through-holes (301a). On the inner walls of through-holes (301a), conductive film (301b) is formed. In addition, substrate 300 has space (R21) whose configuration corresponds to the external shape of electronic component 400.

On the surfaces (both surfaces) of substrate 300, wiring layers (300a, 300b) are formed respectively. Wiring layer (300a) and wiring layer (300b) are electrically connected to each other by means of conductive film (301b) formed in through-holes (301a).

On the lower surface of substrate 300 (the surface on the arrow-Y1 side), insulation layer 410 and wiring layer 310 are laminated in that order. Also, on the upper surface of substrate 300 (the surface on the arrow-Y2 side), insulation layer 420 and wiring layer 320 are laminated in that order. Insulation layers (410, 420) are made of, for example, cured prepreg. Also, wiring layers (310, 320) are made of, for example, copper-plated film.

Electronic component 400 is arranged in space (R21). Insulation layer 420 fills the boundary portions between electronic component 400 and substrate 300.

Insulation layer 410 is formed to coat the lower surface of electronic component 400 and wiring layer (300a). Here, at the predetermined spots, via holes (410a) in a tapered shape are formed to be connected to wiring layer (300a). On the wall and bottom surfaces of via holes (410a), conductor (410b) is formed; via holes (410a) and conductor (410b) form conformal vias. Then, by means of such conformal vias, wiring layer (300a) and wiring layer 310 are electrically connected.

Meanwhile, insulation layer 420 is formed to coat the upper surface of electronic component 400, wiring layer (300b) and terminal electrodes (400a). Here, at predetermined spots, via holes (420a) are formed in a tapered shape to be connected to wiring layer (300b) and terminal electrodes (400a). On the wall and bottom surfaces of via holes (420a), conductor (420b) is formed; via holes (420a) and conductor (420b) form conformal vias. Then, wiring layer (300b) and terminal electrodes (400a) are electrically connected to wiring layer 320 by means of such conformal vias. Here, wiring layer 320 and conductor (420b) are made of, for example, copper-plated film. Therefore, reliability is high in the connection areas between electronic component 400 and wiring layer 320.

Electronic component 400 is completely enveloped by insulation layers (410, 420). In doing so, electronic component 400 is protected by insulation layers (410, 420) while being fixed to a predetermined position.

Regarding via holes (420a) of electronic component 400, the same as in via holes (201a, 202a) of electronic component 200 described previously, diameter (T21) shown in FIG. 19B (corresponding to FIG. 4B), for example, is preferred to be set in the range of 30-70 μm, more preferably 50-60 μm. Height (T22) of via holes (420a) is preferred to be set in the range of 5-15 μm, more preferably at 10 μm. The aspect ratio (height T22/diameter T21) of via holes (420a) is preferred to be set in the range of 0.07-0.33, more preferably 0.07-0.20.

For the sake of convenience, only one terminal electrode (400a) is shown in the drawing, and its surrounding structure has been described. However, the same applies to the rest of terminal electrodes (400a) as well.

Wiring 20 with a built-in electronic component may be manufactured by a worker who carries out the series of processes shown in FIG. 15 previously, for example. In step (S11), diameter (T21), height (T22) and aspect ratio (height T22/diameter T21) of via holes (420a) are determined. More specifically, the worker determines the following values: diameter (T21) in the range of 30-70 μm; height (T22) in the range of 5-15 μm; and aspect ratio in the range of 0.07-0.33.

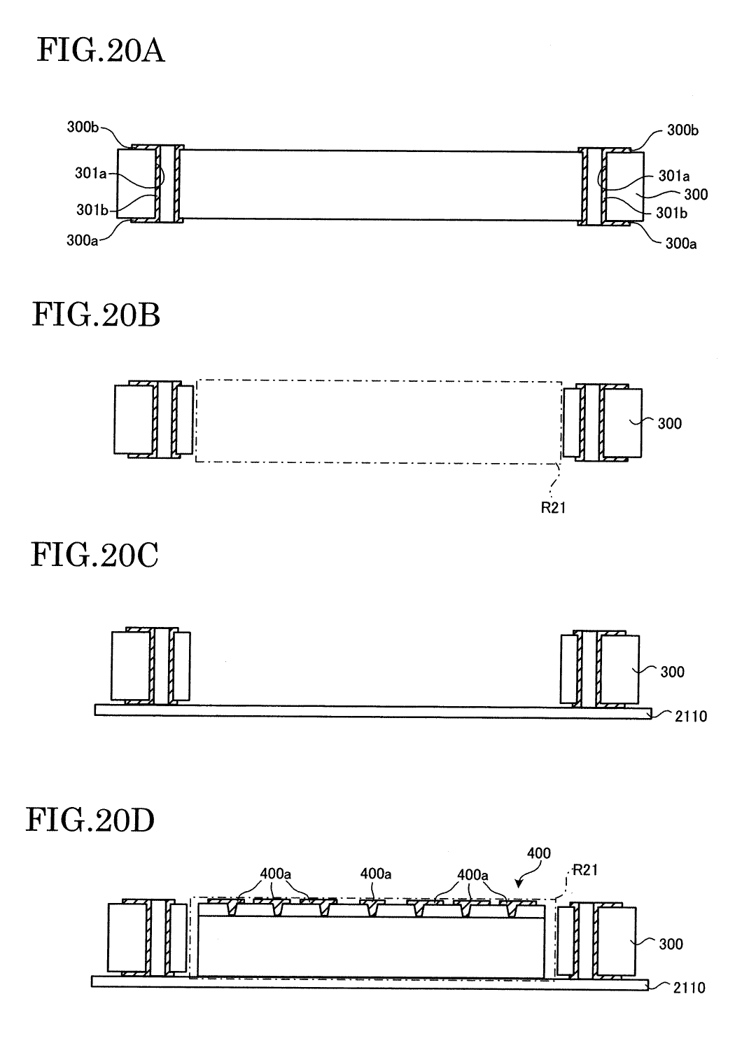

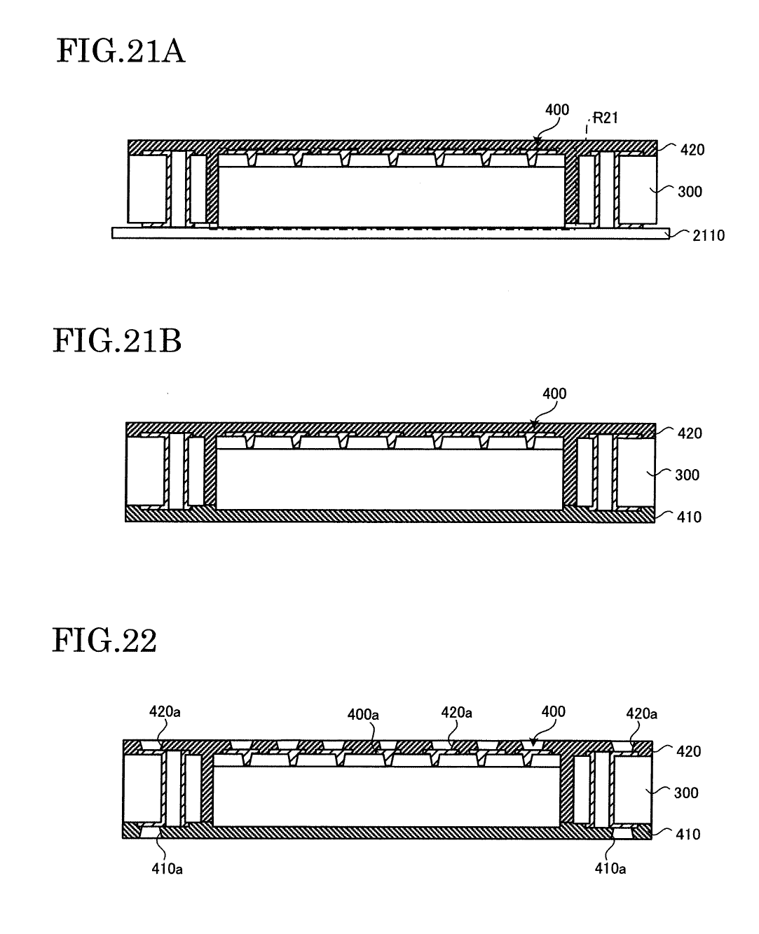

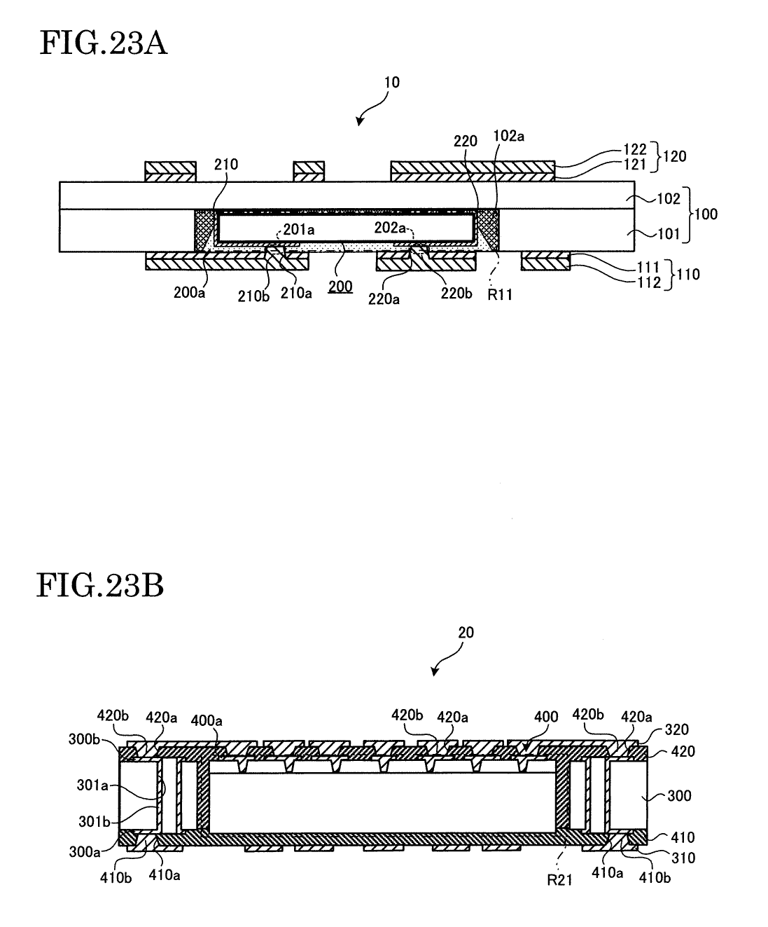

In step (S12), electronic component 400 is embedded through the steps shown in FIGS. 20A-21B, for example.

More specifically, substrate 300 having through-holes (301a) and conductive film (301b) along with wiring layers (300a, 300b) is prepared as shown in FIG. 20A, for example. Substrate 300 corresponds to a core of wiring board 20 with a built-in electronic component.

Space (R21) is formed in substrate 300 by making a hollow section using a laser or the like as shown in FIG. 20B, for example.

As shown in FIG. 20C, for example, carrier 2110 made of polyethylene terephthalate (PET), for example, is arranged on one side of substrate 300. Carrier 2110 is adhered to substrate 300 by lamination, for example.

As shown in FIG. 20D, at room temperature, for example, electronic component 400 is mounted on carrier 2110 (specifically in space R21) in such a way that terminal electrodes (400a) of electronic component 400 face upward (the side opposite carrier 2110). The surfaces of terminal electrodes (400a) are roughened. Such roughened surfaces of terminal electrodes (400a) are usually formed when the electrodes are formed. However, if necessary, the surfaces may be roughened using chemicals or the like after the electrodes are formed.

As shown in FIG. 21A, insulation layer 420 is formed to coat electronic component 400 and substrate 300 using a vacuum laminator, for example. In doing so, terminal electrodes (400a) are coated with insulation layer 420. Furthermore, insulation layer 420 is melted by heat and fills space (R21). Accordingly, electronic component 400 is fixed to a predetermined position.

Carrier 2110 is peeled and removed from the lower surface (the surface opposite insulation layer 420) of substrate 300. As shown in FIG. 21B, for example, insulation layer 410 is formed on the lower surface of substrate 300. In doing so, electronic component 400 is embedded in substrate 300.

In step (S13) of FIG. 15, conductive patterns are formed on electronic component 400 using a semi-additive method, for example. More specifically, first, via holes (410a, 420a) are formed in insulation layers (410, 420) using a laser or the like as shown in FIG. 22. Both surfaces of electronic component 400 are coated with patterned resist, for example, and electrolytic plating is performed selectively on areas where the resist is not formed. In doing so, wiring layers (310, 320) as conductive patterns and conductors (410b, 420b) are formed. Instead of a semi-additive method, a subtractive method may also be used for forming wiring layers (310, 320).

Electrodes are formed by chemical gold plating or the like according to requirements, and carries out external processing, warping correction, conductivity inspection, exterior inspection and final inspection. Accordingly, wiring board 20 with a built-in electronic component is complete as shown previously in FIG. 19A.

The same effects described in the First Embodiment may be achieved in wiring board 20 with a built-in electronic component and its manufacturing method according to the present embodiment.

So far, wiring boards and their manufacturing methods according to the embodiments of the present invention have been described. However, the present invention is not limited to such. For example, the present invention may also be carried out by the following modifications.

Via holes (201a, 202a, 410a, 420a) are not limited to those which form conformal vias. For example, as shown in FIGS. (23A, 23B), those via holes may be filled with conductors (210b, 220b, 410b, 420b) and form filled vias.

Terminal electrodes (210, 220) of electronic component 200 are not limited to those with a U-shape. They may be configured to be a pair of flat-board electrodes sandwiching capacitor body 201.

Any type of electronic component may be used for electronic component 200; for example, other than passive components such as a capacitor, resistor, coil or the like, active components such as an IC chip or the like may also be used.

In the above embodiments, the quality, size, the number of layers and so forth of each layer may also be modified.

For example, to reduce manufacturing costs or the like, wiring board 10 with a built-in electronic component featuring a simple structure as shown previously in FIG. 1 may be preferred. However, the present invention is not limited to such. For example, to achieve high functionality or the like, after the structure shown in FIG. 1 is complete, a lamination process may further be carried out to make it an even multilayer (for example, eight-layer) wiring board with a built-in electronic component.

The order of the steps in the above embodiments may be changed within a scope that will not deviate from the gist of the present invention. Also, one or more steps may be omitted according to usage requirements or the like.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board comprising:
a substrate having an opening section;
an electronic component having an electrode and arranged in the opening section;
an insulative material to be filled in the gap between the substrate and the electronic component in the opening section; and
a first conductive layer formed on the insulative material and including a first conductive pattern,
wherein a via hole is formed in the insulative material, the electrode of the electronic component and the first conductive pattern are connected by means of the via hole, the height of the via hole is set in the range of 5-15 μm, and the aspect ratio of the via hole is set in the range of 0.07-0.33.

2. The wiring board according to claim 1, wherein the aspect ratio of the via hole is set in the range of 0.07-0.20.

3. The wiring board according to claim 1, wherein the height of the via hole is set at 5 μm and the aspect ratio is set in the range of 0.07-0.17.

4. The wiring board according to claim 1, wherein the height of the via hole is set at 10 μm and the aspect ratio is set in the range of 0.14-0.33.

5. The wiring board according to claim 4, wherein the height of the via hole is set at 10 μm and the aspect ratio is set in the range of 0.14-0.20.

6. The wiring board according to claim 1, wherein the height of the via hole is set at 15 μm and the aspect ratio is set in the range of 0.21-0.30.

7. The wiring board according to claim 1, further comprising a second conductive layer formed on at least one surface of the substrate and including a second conductive pattern, wherein the first conductive layer and the second conductive layer are formed on the same level.

8. The wiring board according to claim 1, wherein the insulative material contains two resins having elastic moduli that are different from each other, and, of the two resins, the via hole is formed in the resin that has a lower elastic modulus.

9. The wiring board according to claim 1, wherein the electronic component is either a chip capacitor or a chip resistor.

10. The wiring board according to claim 1, wherein the substrate contains a reinforcing material.

11. A method for manufacturing a wiring board, comprising:
preparing a substrate having an opening section;
arranging an electronic component having an electrode in the opening section;
filling an insulative material in the gap between the substrate and the electronic component in the opening section;
forming a first conductive layer including a first conductive pattern on the insulative material;
forming a via hole with a height in the range of 5-15 μm and an aspect ratio in the range of 0.07-0.33; and
connecting the electrode of the electronic component and the first conductive pattern by means of a via hole.
